(19) United States
(12) Patent Application Publication
(10) Pub. No.: US 2020/0243240 A1
(43) Pub. Date: Jul. 30, 2020

(54) ISOLATED POWER CONVERTER WITH MAGNETICS ON CHIP

(71) Applicant: Analog Devices, Inc., Norwood, MA (US)

(72) Inventor: Baoxing Chen, Westford, MA (US)

(73) Assignee: Analog Devices, Inc., Norwood, MA (US)

(21) Appl. No.: 16/840,209

(22) Filed: Apr. 3, 2020

Related U.S. Application Data
(63) Continuation of application No. 14/826,083, filed on Aug. 13, 2015.
Application No. 14/826,083 is a division of application No. 13/538,953, filed on Jun. 29, 2012, now abandoned.
(60) Provisional application No. 61/503,578, filed on Jun. 30, 2011.

(51) Int. Cl. H01F 5/00; H01F 27/28; H01L 23/522; H02M 3/335; H01F 5/06

(52) U.S. Cl. CPC H01F 5/003; H01F 27/2804; H01L 23/5227; H01F 2027/2809; H01F 5/06; H01L 2924/0002; H02M 3/335

(57) ABSTRACT

An integrated circuit fabricated with a number of layer may include a substrate, a transformer having a first winding, a second winding and a magnetic core. The first winding and the second winding may surround the magnetic core. The transformer may be disposed above a first side of the substrate. A flux conductor may be disposed on a second surface of the substrate opposite to the first surface.

### PRIORITY CLAIM

This application is a continuation claiming the benefit of U.S. patent application Ser. No. 14/826,083, filed Aug. 13, 2015, and entitled “Isolated Power Converter With Magnetics On Chip,” which is hereby incorporated herein by reference in its entirety.

U.S. patent application Ser. No. 14/826,083 is a divisional claiming the benefit of U.S. patent application Ser. No. 13/538,953, filed Jun. 29, 2012, and entitled “Isolated Power Converter With Magnetics On Chip,” which is hereby incorporated herein by reference in its entirety.

U.S. patent application Ser. No. 13/538,953 claims the benefit of U.S. Provisional Patent Application Ser. No. 61/503,578, filed Jun. 30, 2011, and entitled “Isolated Power Converter With Magnetics On Chip,” which is hereby incorporated herein by reference it its entirety.

### BACKGROUND

The subject matter of this application is directed to magnetic circuits implemented on an integrated circuit for providing functionality derived from magnetic circuits, e.g. voltage conversion.

Transformers with air core magnetic circuits have limitations due, in part, to high resistance and low inductance of the air core magnetic circuits. For example, in air core magnetic circuits power may be radiated back to the power plane or ground plane of an integrated circuit (IC) which may affect the electromagnetic interference (EMI). To mitigate the effects of EMI in an air core magnetic circuit, designers must concentrate a great deal of effort in designing the physical parameters of the circuit and the windings including the air core. The effect of EMI is particularly important when applying high frequency signals because EMI is proportional to the frequency. Printed circuit board (PCB) designers must also be concerned with EMI effects due to high currents that are generated. Radiated power is also a problem as it may interfere with other circuits that are not connected to the PCB.

In addition, air core magnetic circuits are not efficient and the packaging of these circuits may limit the power that can be provided. For example, the power dissipation on a chip may limit the power that can be provided by an on-chip transformer. Thus, the amount of power that can be provided is limited by the efficiency of the circuit and the how much power the packaging can handle. Oftentimes too much additional power needs to be supplied to overcome the power lost due to the inefficiency of the air core magnetic circuits.

To overcome the limitation of air core magnetic circuits, designers include magnetic cores in the transformers to increase winding inductance and power conversion efficiency resulting in lower inductor peak current and reduced power consumption. The increased winding inductance and power conversion efficiency also reduces interference with other components because lower switching frequencies can be used and the magnetic flux is more constrained by the addition of the magnetic core. Including magnetic cores in transformers increases the inductance per unit area which provides higher energy densities and allows device miniaturization.

Transformers with magnetic cores can be constructed using isolated converters. Isolated converters provide electrical isolation between interrelated circuits. Isolated converters can be used, for example, when circuits need to be protected from signal spikes or surges. However, existing isolated transformers can require large amount of space. In addition, challenges exist to improve efficiency and to sufficiently isolate the transformers from other circuit components when the transformers are in close proximity to other circuit component.

### BRIEF DESCRIPTION OF THE DRAWINGS

FIGS. 1(a) and 1(b) illustrate exemplary configurations of an on-chip transformer according to embodiments of the present invention.

FIG. 2 illustrates an exemplary configuration of an on-chip transformer having a flux conductor according to an embodiment of the present invention.

FIG. 3 illustrates an exemplary configuration of an on-chip transformer with magnetic core according to an embodiment of the present invention.

FIG. 4 illustrates an exemplary configuration of an on-chip transformer with two magnetic cores according to an embodiment of the present invention.

FIG. 5 illustrates an exemplary configuration of an on-chip transformer with magnetic core according to an embodiment of the present invention.

FIG. 6 illustrates a cross-sectional view of an integrated circuit according to an embodiment of the present invention.

FIG. 7 illustrates a power converter system that can use an on-chip transformer having magnetic core according to an exemplary embodiment of the present invention.

FIG. 8 illustrates an exemplary configuration of an on-chip transformer with magnetic core and a flux conductor disposed on a same side of a substrate according to an embodiment of the present invention.

### DETAILED DESCRIPTION

Embodiments of the present invention may provide for an integrated circuit with a transformer having one or more windings wrapped around a magnetic core that provides a pathway for magnetic flux. A dielectric material may be included to provide electrical insulation between the magnetic core and the winding(s). The transformer may be provided on a substrate. The winding(s) and the magnetic core may be oriented to provide a pathway for magnetic flux in a direction that is parallel to a surface of the substrate on which the transformer is formed. A flux conductor may be provided on another surface of the substrate to improve flux conduction through the transformer. The integrated circuit may be fabricated with a number of layers.

A transformer having a first winding and a second winding may have the first winding surrounding a first portion of the magnetic core and the second winding surrounding a second portion of the magnetic core. At least one of the first windings and the second windings can occupy several layers of the number of layers of the integrated circuit. The magnetic core can also occupy several layers of the number of layers of the integrated circuit.

The magnetic core can be a solid core, can include a plurality of voids or can be a multi-segment core having a dielectric material provided in at least one void between adjacent segments. A single bar core has the most area efficiency, as a pair of cores on the same surface will occupy larger area to provide the same flux conductance. However, using a single bar core may increase EMI due to leakage flux. The integrated circuit can include a second magnetic core disposed adjacent to the magnetic core having the first and second windings. If the magnetic core having the first and second windings is disposed on one side of a substrate, the second magnetic core can be provided on the opposite side of the substrate. The second magnetic core can help to “close” the flux loop without the need for extra surface area on the integrated circuit. The second magnetic core can simply be a ferrite loaded epoxy layer or other films with magnetic permeability larger than one deposited or coated.

The magnetic core can include an opening through which the first winding and the second winding surround the magnetic core. With the magnetic core having an opening, the first winding can surround the magnetic core on one side of the opening and the second winding can surround the magnetic core on the opposite side of the opening.

The first winding and second winding can surround the same portion of the magnetic core. With such a configuration, the first and second windings can be interwound around the same portion of the magnetic core without contacting each other. A dielectric material can also be provided between the interwound windings and the magnetic core to provide isolation between the windings and between the windings and the magnetic core.

Embodiments of the transformer provided on the integrated circuit may include two magnetic cores having one or more windings surrounding each of the magnetic cores. For example, a first magnetic core can be surrounded by the first winding and a second magnetic core can be surrounded by the second winding. Multiple windings may also surround each of the magnetic core and each winding can surround multiple magnetic cores. For example, a first magnetic core can be surrounded by a first winding and a second winding and a second magnetic core can be surrounded by a first winding and a second winding. The windings can be interwound around the same portion of the respective magnetic core without contacting each other.

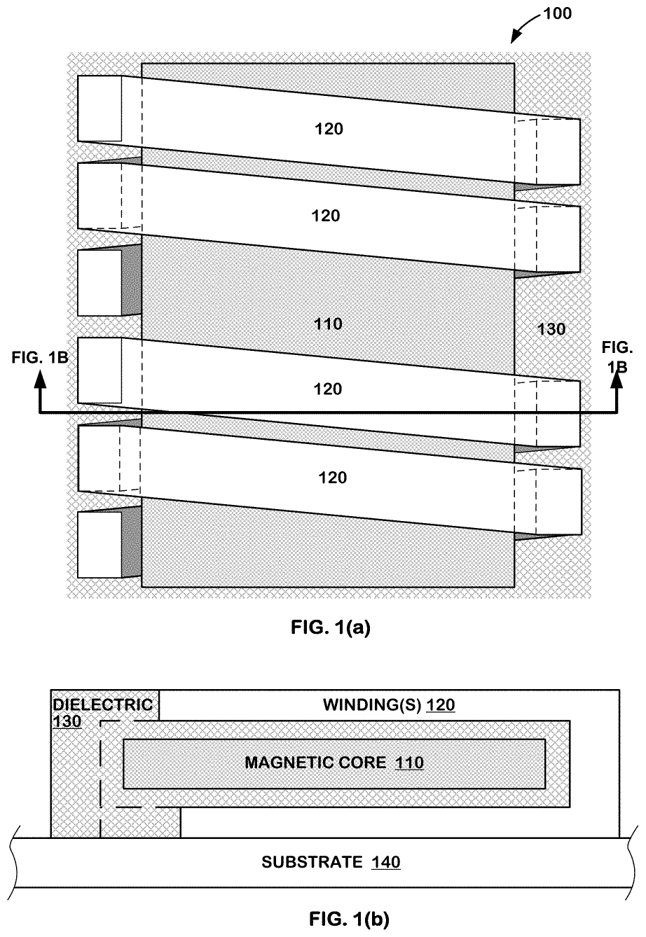

FIGS. 1(a) and 1(b) illustrate exemplary configurations of an on-chip transformer according to embodiments of the present invention. FIG. 1(a) illustrates a top view of an on-chip transformer 100 according to an embodiment of the present invention. The transformer 100 may include a magnetic core 110 providing a pathway for magnetic flux, one or more windings 120 wrapped around the magnetic core 110, and a dielectric material 130 providing electrical insulation between the magnetic core 110 and the winding(s) 120.

The magnetic core 110 providing a pathway for the magnetic flux may occupy several layers of the number of layer of an integrated circuit. For example, a first winding 120 may surround the magnetic core 110 on a plurality of sides of the magnetic core 110 through a first portion of the several layers and a second winding 120 may surround the magnetic core on a plurality of sides of the magnetic core 110 through a second portion of the several layers. As shown in FIG. 1(a), the first winding 120 may surround the magnetic core 110 on a plurality of sides of the magnetic core 110 in a first portion of the magnetic core 110 and the second winding 120 may surround the magnetic core 110 on a plurality of sides of the magnetic core 110 in a second portion of the magnetic core 110, which is different from the first portion of the magnetic core 110. The first and second windings 120 may surround the magnetic core 110 such that the windings 120 circle the magnetic core 110.

FIG. 1(b) illustrates a sectional view of the transformer 100 of FIG. 1(a). As illustrated, the transformer 100 may be built on substrate 140. The magnetic core 110 and winding(s) 120 may be oriented to conduct magnetic flux in a direction that is parallel to a surface of the substrate 140 on which the transformer 100 is formed. The dielectric material 130 provided between the magnetic core and winding(s) 120 may be an isolation layer. The isolation layer may be an insulation layer with high dielectric breakdown such as polyimide, silicon dioxide, silicon nitride and the like. The magnetic core 110 layers can be layers with high permeability such as NiFe (nickel ferrite) and FeCo (ferrite cobalt)-based alloys.

The orientation of the magnetic core 110 and winding(s) 120 allows the transformer 100 to be manufactured according to conventional integrated circuit manufacturing techniques. Using semiconductor masks and photolithography, the winding(s) 120, dielectric material 130 and magnetic core 110 may be built up in multiple layers of material depositions. In one example, the winding traces that form a “rear surface” of the transformer 100, a portion of the transformer that contacts the substrate 140, may be built up in a first stage of manufacture. The application of a dielectric layer 130 may occur in a subsequent manufacturing stage to fill in interstitial regions between the winding traces and also to cover the winding traces. In another stage, materials representing the magnetic core 110 may be laid upon the dielectric layer 130. Additional deposition of dielectric material may be applied to encase the magnetic core 110 in the dielectric. In a late stage, metallic material may be deposited on exposed regions of the rear winding traces to build up “side” traces. Further, metallic material may be deposited on the dielectric-covered front side of the magnetic core 110 to build up traces on the front side of the transformer 100 and complete the winding(s) 120.

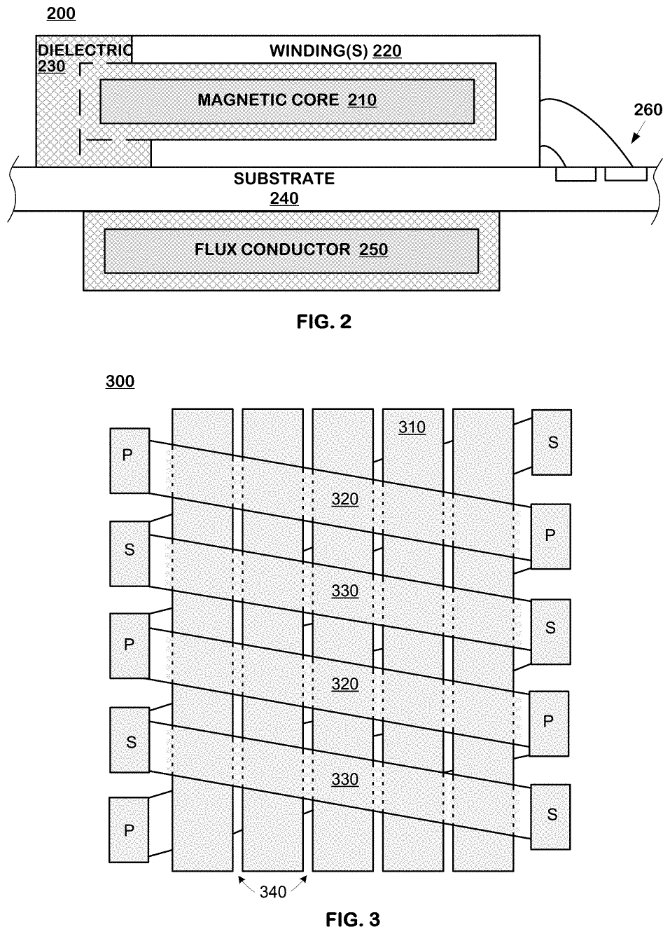

FIG. 2 illustrates an exemplary configuration of an on-chip transformer 200 having a flux conductor according to an embodiment of the present invention. As shown in FIG. 2, the structure of the transformer 200 can include magnetic core 210, one or more windings 220 wrapped around the magnetic core 210, a dielectric material 230, a substrate 240, and a flux conductor 250. One or more circuit components 260 may be disposed on the substrate 240. The one or more circuit elements may be coupled to the windings 220.

The flux conductor 250 can be provided on an opposite side of substrate 240 to the magnetic core 210. Other arrangements of the magnetic core 210, the flux conductor 250 and the substrate 240 are possible. The flux conductor 250 can be provided directly on the surface of the substrate 240. Alternatively, a dielectric can be disposed between the flux conductor 250 and the substrate 240. The dielectric can be provided on one or more sides of the flux conductor 250. The flux conductor 250 can provide an additional flux path whereby magnetic flux from magnetic core 210 may pass to flux conductor 250. The flux conductor 250 may be affixed to the substrate 240 by epoxy or built up on substrate 240 by known processes. The flux conductor 250 may be provided as a film of magnetic material sputtered onto the surface of the substrate 240. The flux conductor 250 may be fabricated from the same material as used for the magnetic core 210. For example, the flux conductor 250 can be made of materials of high permeability such as CoTaZr (cobalt tantalum zirconium) NiFe (nickel ferrite) and FeCo (ferrite cobalt)-based alloys.

The transformers 100 and 200 may include connecting traces to interconnect terminals of the transformer with other circuit components, other dielectric layers to encase the transformer in insulating materials and prevent unintended electrical contact with other components, shielding materials as necessary to reduce electro-magnetic interference with nearby electrical components, and other substrate materials that may provide mechanical stability to the transformer. Although not shown in FIGS. 1(a), 1(b) and 2, the principles of the present invention find application with any of these additional features.

FIG. 3 illustrates an exemplary configuration of an on-chip transformer 300 with magnetic core according to an embodiment of the present invention. Transformer 300 may include on-chip magnetic core 310, a first winding 320 and a second winding 330. The configuration of the transformer 300 may have a first winding 320 interwound with a second winding 330 as each spirals around the on-chip magnetic core 310. The on-chip magnetic core 310 may pass through the center of the interwound first winding 320 and second winding 330.

The on-chip magnetic core 310 may be formed as a single core (shown in FIG. 1(a)) or may be formed with voids 340 between the magnetic bars. The voids 340 may be a predetermined distance (for example, 1-10 micrometers) to alter the shape anisotropy of the magnetic core 310 and provide enhanced permeability. The voids 340 may be filled with a dielectric or electric insulating material. To minimize the reduction of the total core 310 cross-sectional area, the bars of the core 310 can be arranged to make the voids 340 narrow. The voids 340 may alter the shape anisotropy of the magnetic core 310 and provide enhanced permeability. High permeability will lead to high inductance, high efficiency and higher energy density. The voids 340 also may enhance the permeability by limiting the generation and transmission of eddy currents in the magnetic core 310 due to magnetic flux.

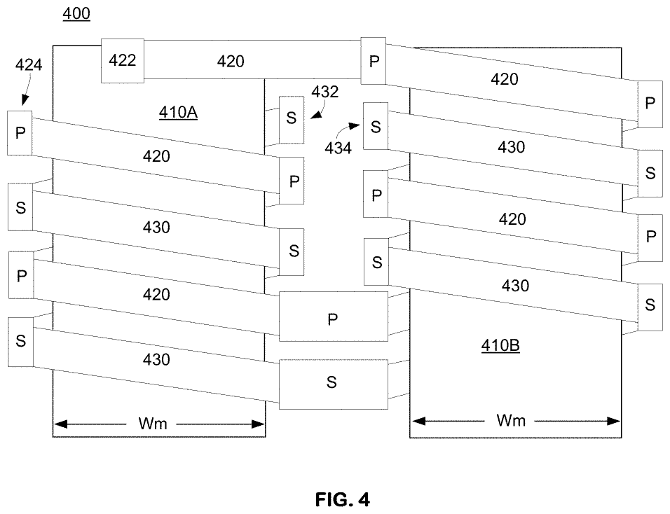

FIG. 4 illustrates an exemplary configuration of an on-chip transformer 400 with two magnetic cores according to an embodiment of the present invention. The on-chip transformer 400 may include a first core 410A, a second core 410B, a primary winding 420, and a secondary winding 430. The primary winding 420 may wrap around the second core 410B and cross over to the first core 410A. The primary winding 420 may also wrap around first core 410. Similarly, the second winding 430 may wrap around the second core 410B and cross over to the first core 410, where the second winding 430 may also wrap around the second core 410B. The primary winding 420 and the secondary winding 430 may spiral around the first core 410A and the second core 410B. At least one of the first core 410A and the second core 410B may include a plurality of voids and a plurality of magnetic bars, as shown in FIG. 3.

The primary winding 420 may include a first terminal 422 and a second terminal 424. As shown in FIG. 4, the first and the second terminal of the primary winding can be disposed on the opposite ends of the primary winding 420. The secondary winding 430 may include a first terminal 432 and a second terminal 434. As shown in FIG. 4, the first and second terminals of the secondary winding 430 may be disposed on the opposite ends of the secondary winding. The first terminal 422 of the primary winding 420 and the first terminal of the secondary winding 430 may be arranged near the first core 410A. The second terminal 424 of the primary winding 420 may be arranged near the first core 410A and the second terminal 434 of the secondary winding 430 may be arranged near the second core 410B.

First and second magnetic cores 410A, 410B may have a width Wm that can be determined to provide the inductance that is needed for a particular application. The primary winding 420 and secondary winding 430 may be arranged around the first and second magnetic cores 410A and 410B such that the direction of the flux from one core is opposite to the direction of the flux from another core. In particular, the orientation of the windings 420 and 430 may be reversed between the first and second core elements 410A and 410B to reduce flux leakage from the transformer 400. In this manner, a driving current may induce flux in the two core elements having opposite direction from each other. This configuration may help provide a flux return path, and reduce flux leakage into surrounding components and EMI radiation. The transformer 400 may be mounted within a semiconductor substrate such that conductivity of magnetic flux carried by the core extends in a direction parallel to a surface of the substrate.

During manufacture, the hard axis of the magnetic core material may be controlled to align to the direction of magnetic flux that will be generated by the transformer during operation. Aligning the hard axis with the direction of flux is expected to reduce switching losses that may occur during operation of the transformer.

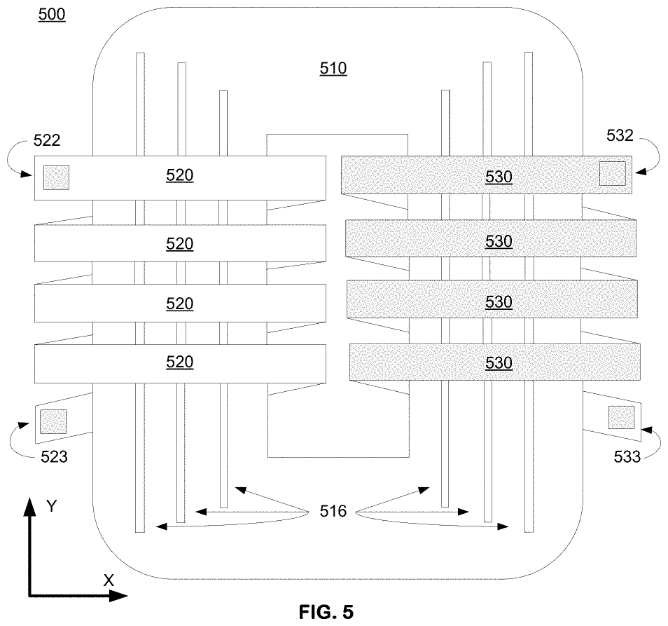

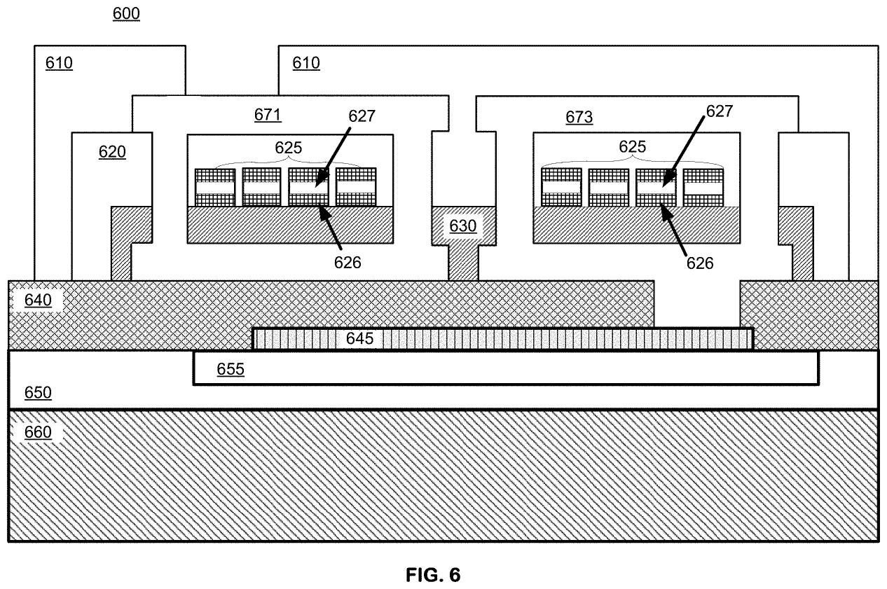

FIG. 5 illustrates an exemplary configuration of an on-chip transformer 500 with magnetic core according to an embodiment of the present invention. The on-chip transformer 500 may include magnetic core 510, a first winding 520 and a second winding 530. The core 510 may have a shape of a rectangle with an opening in the center. The core 510 may have a shape of a rectangle with rounded edges. The core 510 may have a length that is longer than a width of the core 510.

The magnetic core 510 may be a solid magnetic core. In another embodiment, portions of the core 510 may have a plurality of voids 516. The number of voids 516 may be any number so long as the core 510 provides the magnetic flux needed for the particular application. The plurality of voids 516 may be provided in portions of the core that are on either side of the opening in the center of the core 510. The voids 516 may be filed with insulating material or a dielectric material that can change the anisotropy and enhance magnetic permeability.

The first winding 520 and the second winding 530 may be wrapped around portions of the core 510. For example, as shown in FIG. 5, the first winding 520 may be wrapped around the core on one side of the opening and the second winding 530 may be wrapped around the core on another side of the opening. The first and second winding 520, 530 may be centered on the portions of the core 510 that is being wrapped around. The first and second winding 520, 530 may be wrapped around portion of the core 510 that have the voids 516. The first winding 520 may extend between input and output terminals 522, 423 provided on one side of the core 510 and the second winding 530 may extend between input and output terminals 532, 533 provided on another side of the core 510.

Magnetic flux in core 510 may travel circularly through the ring-shaped core. During manufacture, the anisotropic direction may be controlled such that the easy axis is along the Y direction and hard axis is along the X direction. Flux generated by the windings may travel easily with the core along the hard axis (X direction). The majority of the flux can be switched along the hard axis to minimize hysteric losses.

As the flux approached the ends (at the Y axis) of the magnetic core 510, the flux may tend to escape instead of follow the shape of the magnetic core 510 (in the X axis). With the exemplary embodiments shown in FIG. 5, less flux may escape out of the top and bottom of the magnetic. A benefit may be less induced noise by limiting the radiation of the magnetic flux in comparison to other designs. However, some additional loss may incur with the flux traveling in the top and bottom areas along the x-axis, the easy axis. For practical designs, one design may be selected over another depending on factors that are important to the applications.

The on-chip transformer 500 may be mounted within a semiconductor substrate such that conductivity of magnetic flux carried by the core 510 extends in a direction parallel to a surface of the substrate.

FIG. 6 illustrates a cross-sectional view of an integrated circuit 600 according to an embodiment of the present invention. The transformer 600 may be built in an integrated circuit chip. The integrated circuit chip may include substrate 660, insulating substrate 650, electrode 645, active components layer 655, insulating layers 640, a first winding 671, a second winding 673, magnetic core 625, dielectric layers 630, 620 and insulating layer 610. Dielectric layers 620 and 630 may be formed to provide sufficient insulation between the primary windings and secondary windings. Dielectric layers 620 and 630 may also provide insulation between the primary windings and the core and between the secondary windings and core.

The magnetic core 625 may be a solid bar with the winding provided around it. The magnetic core 625 may be formed from a plurality of magnetic bars separated by dielectric spacers with the winding provided around the collection of bars. For example, the magnetic core 625 may include sandwich or multilayers of magnetic material 626 and non-conductive dielectric material 627. The spacer layer thickness needs to be optimized for maintaining permeability at high frequency and high efficiency.

Insulating layer 610 can act as an encapsulation to protect the device and can insulate the transformer from external signals, such as high frequency signals emanating from ground planes or power supply planes that may induce parasitic signals on the windings 671 and 673. Insulating layers 640 may insulate windings from the substrate 660.

The optional electrode 645 may act as a connection from any component in the active components layer 655 underneath the transformers to one of the windings. The active component layer 655 may be provided on a face of a substrate facing away from the face of the substrate having the windings 671 and 673. If no connection from the windings to the substrate is needed, the electrode 645 can be not used, and both the primary windings and secondary windings will be insulated from the substrate 660 through dielectric layers 640. Insulating substrate 650 may insulate the optional electrode 645 from substrate 560.

Depending on circuit requirements, windings 671 and 673 may be connected solely to components of the active component layer 655. Alternatively, one of the windings 671 and 673 may be connected solely to the active component layer 655 and another inductor may be connected solely to a printed circuit board (PCB) (now shown in FIG. 6) as design needs dictate. Component(s) of the active component layer 655 each will be configured for specific applications of the integrated circuit.

In addition to fabricating power transformers, the above embodiments may also be used to fabricate feedback transformers.

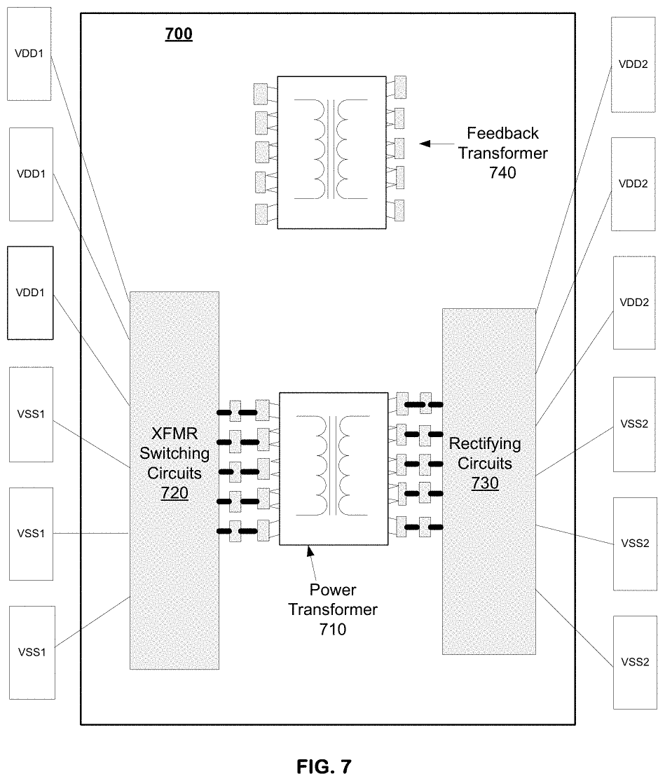

The exemplary embodiments having the above transformer configurations may be applicable to constructing an integrated circuit chip with an on-chip transformer having a magnetic core. FIG. 7 illustrates a power converter system 700 that can use an on-chip transformer having a magnetic core according to an exemplary embodiment of the present invention.

The power converter systems 700 may include a transformer with magnetic core 710, a transformer switching circuit 720 and a rectifying circuit 730. Optionally, feedback transformer 740 may also be provided. The general arrangement of the transformer 710, power switching circuit 720, rectifying circuit 730 and feedback transformer 740 are not the emphasis of the present application. As shown in FIG. 7, the transformer 710 having a magnetic core can be provided on the same die as the power switching circuit 720 and the rectifying circuit 730. In those cases, the optional electrode 645, shown in FIG. 6, may be used to connect the power switching circuit 720 to the primary winding or connect the secondary winding to the rectifying circuit 730.

If a dedicated transformer die is used, the connection from the power switching circuit 720 to the primary winding and the connection from the rectifying circuit 730 to the secondary winding can be achieved through chip-to-chip bond wires as shown. The transformers 710 and/or 740 may be arranged in a plurality of different general configurations as shown in FIGS. 1-6. For example, transformers 710 and 740 can have: spiraled first and second conductor loops with a magnetic core through the center of the spirals; nested spirals in which a first spiraled conductor loop and a second spiraled conductor loop spiral around one another with a magnetic core through the center of the spirals; and stacked spiral magnetic core in the form of a solenoid.

The isolated transformer 710 may be formed on top of the transformer switching IC die, on top of the rectifying IC die, or a dedicated transformer die as shown in FIG. 7. The power converter 700 can further include a feedback transformer die than can also be on the same die as the power transformer 710 or a separate die. In the case of feedback transformer 740 being provided on the same die as the power transformer 710, the feedback transformer 740 can be of similar construction or different construction such as those in stacked spirals, i.e., a top winding and a bottom winding. The feedback transformer 740, although shown with a magnetic core, may have either a magnetic core or an air core.

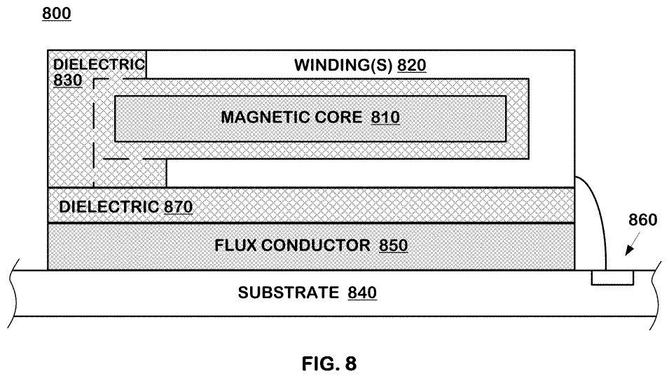

FIG. 8 illustrates an exemplary configuration of an on-chip transformer 800 with magnetic core 810 and a flux conductor 850 disposed on a same side of a substrate 240 according to an embodiment of the present invention. As shown in FIG. 8, the structure of the transformer 800 can include magnetic core 810, one or more windings 820 wrapped around the magnetic core 810, a dielectric material 830, a substrate 840, a flux conductor 850 and a dielectric material 870. One or more circuit components 860 may be disposed on the substrate 840. The one or more circuit elements may be coupled to the windings 820.

The flux conductor 850 can be provided on a side of substrate 840 on which the magnetic core 810 is disposed. A dielectric material 870 cab be disposed between the one or more windings 820 and the flux conductor 850. The flux conductor 850 can provide an additional flux path whereby magnetic flux from magnetic core 810 may pass to flux conductor 850. The flux conductor 850 may be affixed to the substrate 840 by epoxy or built up on substrate 840 by known processes. The flux conductor 850 may be provided as a film of magnetic material sputtered onto the surface of the substrate 840. The flux conductor 850 may be fabricated from the same material as used for the magnetic core 810. For example, the flux conductor 850 can be made of materials of high permeability such as CoTaZr (cobalt tantalum zirconium) NiFe (nickel ferrite) and FeCo (ferrite cobalt)-based alloys.

In the exemplary embodiments, the dielectric materials may be high dielectric breakdown materials such as polyimide, silicon dioxide, silicon nitride and the like. The magnetic core layers and flux conductor layer can be made of materials of high permeability such as CoTaZr (cobalt tantalum zirconium) NiFe (nickel ferrite) and FeCo (ferrite cobalt)-based alloys. Finally, the windings and metal interconnect structures may be formed of an appropriate conductive metal such as gold or copper.

Although the invention has been described above with reference to specific embodiments, the invention is not limited to the above embodiments and the specific configurations shown in the drawings. For example, some components shown may be combined with each other as one embodiment, or a component may be divided into several subcomponents, or any other known or available component may be added. Those skilled in the art will appreciate that the invention may be implemented in other ways without departing from the sprit and substantive features of the invention. The present embodiments are therefore to be considered in all respects as illustrative and not restrictive. The scope of the invention is indicated by the appended claims rather than by the foregoing description, and all changes that come within the meaning and range of equivalency of the claims are therefore intended to be embraced therein.

What is claimed is:

1. An integrated circuit, comprising:
an integrated circuit substrate; and
a transformer formed on one side of the integrated circuit substrate, the transformer including:
a plurality of separated magnetic core bars; and
interwound first and second windings, the plurality of separated magnetic core bars passing through a center of the first winding.

2. The integrated circuit of claim 1, wherein the plurality of separated magnetic core bars are separated by a plurality of voids configured to alter a shape anisotropy of the plurality of separated magnetic bars.

3. The integrated circuit of claim 1, wherein the plurality of separated magnetic core bars are separated by a dielectric material.

4. The integrated circuit of claim 1, wherein the plurality of separated magnetic core bars are parallel to each other.

5. The integrated circuit of claim 1, wherein the interwound first and second windings are configured to produce magnetic flux aligned with a hard axis of the plurality of separated magnetic core bars.

6. The integrated circuit of claim 1, wherein the plurality of separated magnetic core bars pass through a center of the second winding.

7. The integrated circuit of claim 1, wherein the plurality of separated magnetic core bars are a first plurality of separated magnetic core bars, and wherein the transformer further comprises a second plurality of separated magnetic core bars, the first and second windings being configured to induce magnetic flux in a first direction in the first plurality of separated magnetic core bars and in a second direction in the second plurality of separated magnetic core bars.

8. The integrated circuit of claim 1, wherein the plurality of separated magnetic core bars are a first plurality of separated magnetic core bars, and wherein the transformer further comprises a second plurality of separated magnetic core bars, wherein a first portion of the first and second windings wraps about the first plurality of separated magnetic core bars but not the second plurality of separated magnetic core bars, and a second portion of the first and second windings wraps about the second plurality of separated magnetic core bars but not the first plurality of magnetic bars.

9. An integrated circuit, comprising:
a transformer formed on one side of an integrated circuit substrate, and including:
a plurality of magnetic bars positioned with gaps between them, and
first and second windings wrapped around the plurality of magnetic bars, the first winding being wrapped such that a single loop of the first winding wraps around the plurality of magnetic bars.

10. The integrated circuit of claim 9, wherein the plurality of magnetic bars are disposed such that the gaps alter a shape anisotropy of the plurality of magnetic bars.

11. The integrated circuit of claim 9, further comprising a dielectric material in the gaps.

12. The integrated circuit of claim 9, wherein the first and second windings are interwound.

13. The integrated circuit of claim 9, wherein the first and second windings are configured to produce magnetic flux aligned with a hard axis of the plurality of magnetic bars.

14. The integrated circuit of claim 9, wherein the first and second windings are interwound with each other about the plurality of magnetic bars to induce magnetic flux in a first direction.

15. The integrated circuit of claim 14, wherein:
the plurality of magnetic bars are a first plurality of magnetic bars,
the transformer comprises a second plurality of magnetic bars,
the first and second windings are interwound with each other about the second plurality of magnetic bars to induce magnetic flux in a second direction opposite to the first direction.

16. The integrated circuit of claim 9, wherein:
the plurality of magnetic bars are a first plurality of magnetic bars,
the transformer comprises a second plurality of magnetic bars,
a first portion of the first and second windings wraps about the first plurality of magnetic bars but not the second plurality of magnetic bars, and
a second portion of the first and second windings wraps about the second plurality of magnetic bars but not the first plurality of magnetic bars.

17. An integrated circuit, comprising:
a transformer formed on one side of an integrated circuit substrate, the transformer including:
primary and secondary windings,
a plurality of magnetic core bars,
a dielectric material disposed between adjacent magnetic core bars,
wherein the primary and secondary windings are interwound and wherein the primary winding comprises a loop encompassing the plurality of magnetic core bars.

18. The integrated circuit of claim 17, wherein the plurality of magnetic core bars are disposed such that the dielectric material alters a shape anisotropy of the plurality of magnetic core bars.

19. The integrated circuit of claim 17, wherein the plurality of magnetic core bars are parallel to each other.

20. The integrated circuit of claim 17, wherein:
the plurality of magnetic core bars are a first plurality of magnetic bars,
the transformer comprises a second plurality of magnetic core bars,
a first portion of the primary and secondary windings wraps about the first plurality of magnetic bars but not the second plurality of magnetic bars, and
a second portion of the primary and secondary windings wraps about the second plurality of magnetic bars but not the first plurality of magnetic bars.
